(19) United States
(12) Patent Application Publication
(10) Pub. No.: US 2016/0053370 A1
(43) Pub. Date: Feb. 25, 2016

(54) SCALABLE PROCESSING OF NANOCOMPOSITES USING PHOTON-BASED METHODS

(71) Applicant: THE JOHNS HOPKINS UNIVERSITY, Baltimore, MD (US)

(72) Inventors: James B. Spicer, Columbia, MD (US); Travis J. Dejournett, Baltimore, MD (US)

(21) Appl. No.: 14/782,386

(22) PCT Filed: Apr. 5, 2014
(86) PCT No.: PCT/US14/33110

§ 371 Date: Oct. 5, 2015

Related U.S. Application Data
(63) Continuation of application No. 13/857,312, filed on Apr. 5, 2013, now abandoned.

(51) Int. Cl. C23C 16/04; C23C 16/448; C23C 16/40; C23C 16/48; C23C 16/18

(52) U.S. Cl. CPC C23C 16/047; C23C 16/483; C23C 16/18; C23C 16/405; C23C 16/448

(57) ABSTRACT

Using a modified CVD infusion process and femtosecond laser irradiation, the methods of the present invention demonstrate the ability to create core-shell nanoparticles of metal and metal oxide nanoparticles embedded within the bulk of an optically transparent substrate. With the use of optical masks and multiple precursor chemicals, the inventive methods make it possible to create nanoparticles or core-shell nanoparticles with drastically different compositions in close proximity to each other. Since the mechanism for precursor decomposition is limited to the surface of the nanoparticles within the substrate, it is possible to control the chemistry, size, and shape of nanoparticles within an optically transparent substrate on a nanoscale. The present invention also provides methods of controlling diffusion of a metal or metal oxide precursor compound in a substrate by selectively irradiating the substrate with a wavelength of light which is preferentially absorbed by the substrate and not the precursor, allowing preferential diffusion of the precursor compounds in the irradiated areas.

### REFERENCE TO RELATED APPLICATIONS

This application claims the benefit of U.S. patent application Ser. No. 13/857, 312, filed on Apr. 5, 2013, which is hereby incorporated by reference for all purposes as if fully set forth herein.

### BACKGROUND OF THE INVENTION

Many polymer matrix nanocomposites are composed of a random distribution of nanoparticles within a solid polymer matrix. The material properties of these nanocomposites are determined by the size and type of nanofeatures, their distribution in the matrix, and their interaction with the bulk matrix material. Typically, these nanocomposites are engineered to have a specific property and are used as a coating to alter the material properties of a device or structure. They have been synthesized via CVD, thermolysis of chemical precursors, co-sputtering, evaporation, pulsed laser deposition, or by distributing nanoparticles within a liquid monomer solution that is subsequently polymerized. The polymer nanocomposites produced with these methods often result in a random distribution of nanoparticles, rods, cubes, etc. throughout the bulk of the polymer.

It is desirable to be able to pattern polymer nanocomposites in order to tailor their material properties. This has recently been accomplished by preloading a polymer with a silver chemical precursor and selectively decomposing that precursor via a nonlinear multiphoton reaction in regions exposed to intense femtosecond laser irradiation. It was found that using this process, they were able to three-dimensionally control the placement of large (300 nm) nanofeatures composed of an agglomeration of smaller nanoparticles within a polymer matrix. A similar mechanism using femtosecond laser irradiation has also been used to selectively grow PbS nanoparticles in a silica xerogel loaded with PbS chemical precursors.

The use of femtosecond lasers to induce chemical reactions on the nanoscale has typically been performed to induce specific chemical changes on the surface of metallic nanoparticles via photothermal heating. Metallic nanoparticles exhibit a large optical absorption at their surface plasmon resonance (SPR). The SPR occurs due to a strong coupling of free electrons to a specific frequency of light and is highly dependent on both the size and shape of a metallic nanoparticle as well as the dielectric properties of the matrix in which it is embedded. By exposing metallic nanoparticles to femtosecond laser irradiation, it is possible to rapidly heat a nanoparticle via photothermal heating. This has been used to denature proteins in the immediate vicinity of nanoparticles and to form vapor bubbles on the surface of gold nanoparticles in water. The SPR of metallic nanoparticles can be red or blue shifted by altering the geometry of the nanoparticle itself and by altering the dielectric properties of the medium in which it is embedded. It has also been found that by using femtosecond lasers, pre-existing core-shell nanoparticles could be melted, reshaped, or fused together resulting in large shifts of their SPR.

However, the prior art processes to date utilize longer laser exposure times and are limited in scale due to diffraction limited optical effects and result in incorporation of nanoparticles randomly throughout a substrate and do not allow for the nanoscale patterning of preexisting nanofeatures within a matrix or for the creation of more complicated nanostructures such as core-shell nanoparticles.

### SUMMARY OF THE INVENTION

The photoengineering-based processing methods of one or more embodiments of the present invention described here can be used to produce specific functional behaviors in large volumes of materials.

In accordance with an embodiment, the present invention provides a method for making a nanocomposite comprising: a) contacting an optically transparent substrate with at least one organometallic metal precursor compound such that the organometallic metal precursor compound diffuses into the optically transparent polymer substrate to create a organometallic metal precursor-polymer composite; b) decomposing the organometallic metal precursor-polymer composite of a) and creating a first nanocomposite substrate comprising metal nanoparticles dispersed in the substrate; c) contacting the first nanocomposite substrate of b) with at least one metal oxide precursor compound such that the metal oxide precursor compound diffuses into the first nanocomposite substrate of c) to create a metal oxide precursor-nanocomposite substrate; and d) selectively exposing one or more discrete areas of the a metal oxide precursor-nanocomposite substrate of c) to a light source at a wavelength in which the metal nanoparticles in the metal oxide precursor-nanocomposite substrate absorb the laser light in a significantly greater amount than the other compounds in the substrate, at a sufficient pulse width, pulse repetition and average pulse fluence, and for a sufficient period of time to decompose the metal oxide precursor compound in the metal oxide precursor-nanocomposite substrate creating a nanocomposite comprising a polymer substrate having nanoparticles comprising a metal core and a metal oxide shell in the discrete areas.

In accordance with another embodiment, the present invention provides a method for making a nanocomposite comprising: a) contacting an optically transparent substrate with at least one photocatalytic decomposable metal oxide precursor compound such that the decomposable metal oxide precursor compound diffuses into the optically transparent polymer substrate to create a decomposable metal oxide precursor-polymer composite; b) decomposing the photocatalytic decomposable metal oxide precursor-polymer composite of a) and creating a first nanocomposite substrate comprising metal oxide nanoparticles dispersed in the substrate; c) contacting the photocatalytic nanocomposite substrate of b) with at least one decomposable metal precursor compound such that the decomposable metal precursor compound diffuses into the photocatalytic nanocomposite substrate of c) to create a decomposable metal precursor-nanocomposite substrate; and d) selectively exposing one or more discrete areas of the a decomposable metal precursor-nanocomposite substrate of c) to a light source at a wavelength in which the photocatalytic nanocomposite substrate absorbs the light in a significantly greater amount than that the decomposable metal precursor compound in the substrate, at a sufficient pulse width, pulse repetition and sufficient pulse fluence, and for a sufficient period of time to photocatalytically decompose the decomposable metal precursor compound in the nanocomposite substrate creating a nanocomposite comprising a substrate having nanoparticles comprising a metal oxide core and a metal shell in the discrete areas.

In accordance with a further embodiment, the present invention provides a method for making a nanocomposite comprising: a) placing a optically transparent substrate into a first reaction vessel; b) placing at least one organometallic metal precursor compound into the reaction vessel; c) vaporizing the organometallic metal precursor compound in the first reaction vessel such that the organometallic metal precursor compound diffuses into the optically transparent substrate to create a organometallic metal precursor-substrate composite; d) heating the organometallic metal precursor-composite of c) to decompose the organometallic metal precursor and creating a first nanocomposite substrate comprising metal nanoparticles dispersed in the substrate; e) cooling first reaction vessel and removing remaining organometallic metal precursor compound and decomposition gases; f) placing the first nanocomposite substrate of d) into a second reaction vessel; g) placing at least one metal oxide precursor compound in the second reaction vessel; h) optimizing the oxygen concentration in the second reaction vessel; i) heating the second reaction vessel to allow the metal oxide precursor to subliminate such that the metal oxide precursor compound diffuses into the first nanocomposite substrate of d) to create a metal oxide precursor-nanocomposite substrate; j) selectively exposing one or more discrete areas of the a metal oxide precursor-nanocomposite substrate of i) to a laser beam at a wavelength in which the metal nanoparticles in the metal oxide precursor-nanocomposite substrate absorb the laser light in a significantly greater amount than the other compounds in the substrate, at a sufficient pulse width, pulse repetition and average pulse fluence, and for a sufficient period of time to decompose the metal oxide precursor compound in the metal oxide precursor-nanocomposite substrate creating a nanocomposite comprising a substrate having nanoparticles comprising a metal core and a metal oxide shell in the discrete areas.

In accordance with another embodiment, the present invention provides a method for making a patterned nanocomposite comprising: a) contacting an optically transparent substrate with at least one photocatalytic decomposable metal oxide precursor compound such that the decomposable metal oxide precursor compound diffuses into the optically transparent polymer substrate to create a decomposable metal oxide precursor-polymer composite; and b) selectively exposing one or more discrete areas of the decomposable metal oxide precursor-polymer composite to a light source at a wavelength wherein the optically transparent substrate absorbs the light in a significantly greater amount than the photocatalytic decomposable metal oxide precursor compound; and allowing the photocatalytic decomposable metal oxide precursor compound to diffuse into the discrete areas.

In accordance with another embodiment, the present invention provides a method for making a patterned nanocomposite comprising: a) contacting an optically transparent substrate with at least one photocatalytic decomposable metal precursor compound such that the decomposable metal precursor compound diffuses into the optically transparent polymer substrate to create a decomposable metal precursor-polymer composite; and b) selectively exposing one or more discrete areas of the decomposable metal precursor-polymer composite to a light source at a wavelength wherein the optically transparent substrate absorbs the light in a significantly greater amount than the photocatalytic decomposable metal precursor compound; and allowing the photocatalytic decomposable metal precursor compound to diffuse into the discrete areas.

### BRIEF DESCRIPTION OF THE DRAWINGS

FIG. 1 illustrates where a 2× Ag-FEP nanocomposite was placed in a reaction vessel with an organometallic chemical precursor, the vessel was then evacuated and heated to the vaporization temperature of the precursor. Regions of a 2× Ag-FEP nanocomposite were then selectively exposed to a frequency-doubled femtosecond laser (optical wavelength—400 nm, pulse width—135 fs, pulse repetition frequency—1 kHz, average pulse fluence—90 μJcm⁻²).

FIG. 2 is a schematic time versus temperature evolution diagram showing temperature as a function of distance from a heated nanoparticle for various times after particle irradiation. The regions immediately surrounding the irradiated nanoparticle will experience a temperature rise that depends on the temperature of the nanoparticle and decreases rapidly with time (100-1000 ps) and as a function of distance (10-20 nm) from the nanoparticle.

FIG. 3 depicts a UV/Vis absorption spectrum for an as-prepared 2× Ag-FEP nanocomposite along with corresponding spectra for the same material after laser irradiation in the presence of vaporized tungsten carbonyl and for the neat FEP matrix material.

FIG. 4 depicts a UV/Vis spectra of 2× WO₃-FEP nanocomposites before and after exposure to femtosecond laser irradiation (800 nm, 80 MHz repetition rate, 6 nJcm⁻²) while in the presence of a vaporized silver precursor. The resulting growth of a SPR peak related to WO₃—Ag core-shell nanoparticles can be seen at 430 nm.

FIG. 5 is a TEM micrograph of a 2×Ag-FEP nanocomposite before exposure to femtosecond laser irradiation. A cubic or semi-cubic shape can be observed for certain silver nanoparticles, and through image analysis, the average nanoparticle radius was calculated to be 5 nm.

FIG. 6 is a TEM micrograph of a 2× Ag-FEP nanocomposite after femtosecond laser exposure (400 nm, 1 kHz repetition rate) in the presence of vaporized tungsten carbonyl. Thin shells of tungsten oxide on the order of 5 nm thick surround the roughly cubic-shaped silver nanoparticles.

FIG. 7 is a TEM micrograph of a 2×WO₃-FEP nanocomposite before exposure to femtosecond laser irradiation. The tungsten oxide nanoparticles exhibit a roughly spherical shape with an average radius of 4.3 nm.

FIG. 8 depicts the complicated core-shell geometries that were observed for a 2× WO₃-FEP nanocomposite irradiated by a femtosecond laser with an optical wavelength of 800 nm, a 80 MHz repetition rate, and a pulse energy of 6 nJcm⁻² while in the presence of a vaporized silver precursor. Due to the appearance of larger post-exposure nanoparticles, in addition to the observed size as well as cubic shapes of silver nanoparticles and the observed size as well as spherical shape of tungsten oxide nanoparticles before laser exposure, the large nanoparticles with radii larger than 10 nm exhibiting cubic, semi-cubic, and octahedral shapes are believed to be silver shells surrounding tungsten oxide cores.

FIG. 9 shows the presence of larger nanoparticles and core-shell nanoparticles can be observed in the near surface region when compared to the bulk of the polymer film.

FIG. 10 shows the optical transmission spectra for a matrix polymer (ETFE) along with related spectra when this polymer contains the precursors tungsten hexacarbonyl and palladium hexafluoroacetylacetonate.

### DETAILED DESCRIPTION OF THE INVENTION

Therefore, in accordance with some embodiments, the present invention provides methods for scalable synthetic processes for the production and patterning of substrates, including, for example, polymer matrix nanocomposites (PMNCs), using laser irradiation, such as femtosecond laser irradiation, to target specific functional behaviors in the substrate. The present invention comprises a modified, in situ, chemical vapor deposition (CVD), process termed “nanoinfusion” which is used to nucleate and grow nanoparticles in the bulk of an optically transparent substrate, (a polytetrafluoroethylene-co-hexafluoropropylene (FEP) polymer matrix). Metallic nanoparticles synthesized with this process can have a strong optical absorption at their surface plasmon resonance (SPR) frequency and this property was used to selectively irradiate and pattern nanocomposites via femtosecond, photothermal heating. If the nanoparticle environment includes species used for chemical vapor deposition, the heat causes a localized decomposition of the precursor species in the immediate vicinity of the nanoparticle leading to a variety of core-shell nanostructures.

In one or more embodiments, the present inventive methods were used to grow shells of tungsten oxide around silver nanoparticles within a polymer matrix substrate which is optically transparent to the irradiation wavelength, resulting in a 40 nm red shift in the SPR of the silver nanoparticles in regions of the material exposed to femtosecond laser pulses. The inventive methods have also been adapted to polymer substrates containing tungsten oxide nanoparticles so that the photocatalytic behavior of the particles could be used to the decompose precursor species in the immediate vicinity of the irradiated nanoparticles. These results demonstrate that, by using optical masks and laser processing, it is possible to synthesize nanocomposites with a high degree of control over the location, composition, size, and distribution of nanoparticles within a polymer matrix resulting in patterned materials with tailored electrical, optical, and photocatalytic properties.

As used herein, the term nanocomposite means a material comprised of two or more materials, with at least one of the materials including particles having no dimension greater than about several hundred nanometers (nm). In one or more embodiments, the nanocomposites of the present invention are polymer-based nanocomposite materials which include a filler material of nanoparticles dispersed in the matrix of the polymer substrate. The substrate in which the nanoparticles are dispersed is optically transparent to selected wavelengths of light or electromagnetic radiation which are used to depcompose organometallic metal precursor compounds or metal oxide precursor compounds diffused within the substrate.

As used herein, the term organometallic metal precursor compounds or metal oxide precursor compounds are compounds which when heated to a specific temperature, decompose into a metal or metal oxide nanoparticle within the optically transparent substrate. Examples of such compounds include, but are not limited to with vinyltriethylsilane-(hexafluoroacetylacetonate)silver(I) [Ag(CF₃COCHCOCF₃)(C₈H₁₈—Si)], tungsten carbonyl [W(CO)₆] Palladium(II) hexafluoroacetylacetonate [C₁₀H₂F₁₂O₄Pd], Molybdenum carbonyl [C₆MoO₆], titanium diisopropoxide bis(acetylacetonate) [[(CH₃)₂CHO]₂Ti(C₅H₇O₂)₂], iridium(III) acetyl acetonate [[CH₃COCH═C(O—)CH₃]₃Ir].

As used herein, the term light source can be any source of light which can be tuned to any specific wavelength, such as the absorptive wavelength of organometallic metal precursor compounds, metal oxide precursor compounds, the SPR or related absorption resonances of nanostructures or other chemical properties. Examples of such light sources include lasers, such as fixed-wavelength or tunable sources including pulsed sources such as femtosecond lasers. Examples of these lasers include Ti:sapphire systems that can be frequency-doubled or -tripled using external means, Ti:sapphire systems that can be amplified using various means including chirped-pulse amplification systems, Ti:sapphire systems that can pump optical parametric oscillators and amplifiers.

The wavelengths used in the inventive methods can vary with the light source and composites used. Wavelengths from UV to far infra-red are contemplated within the scope of the inventive methods.

In accordance with one preferred embodiment, the metal atom in the nanoparticle precursor is a transition metal. The transition metal may be Ti, Cr, Fe, Co, Ni, Ta, Zr, Zn, Ta, Hf, Cr, V, W, Ag, Au, Pd or Pt. Alkaline-earth metals, rare-earth metals and Group 3B metals are also useful. For example, the metal may be a non-transition metal such as Al, Tl, Sn, Sb, Ba, In, Pb and Ge. (Metals are defined to include elements that are electrically conductive in the pure state and do not include elements that form semiconductors or insulators such as silicon). The nanoparticles in the present nanocomposite, resulting from the reaction of such nanoparticle precursors, substantially comprise the metals, corresponding compounds or oxides of these metals, as will be readily understood by the skilled artisan.

In accordance with an embodiment, the organometallic metal precursor compound is vinyltriethylsilane-(hexafluoroacetylacetonate)silver(I).

In accordance with an embodiment, the metal oxide precursor compound is tungsten carbonyl.

It will be understood by those of ordinary skill in the art that in some embodiments, the reactions which take place within the substrate are in the presence of oxygen. The amount of oxygen is dependent on the reactions chosen and the pressures used can vary depending on the reaction vessel and amounts of reactants present. In some embodiments the oxygen pressure is in the range of 100 to 1000 torr, including, for example 200, 300, 400, 500, 600, 700 800, 900 torr. In a preferred embodiment, the oxygen pressure is about 400 torr.

In certain embodiments, the optically transparent subtrate is a polymer. The polymer (or matrix polymer) used to make one or more embodiments of the present nanocomposite invention may be either an addition polymer or a condensation polymer. The matrix polymer of the invention can be any natural or synthetic polymer. The matrix polymer of the invention can be of different architecture: linear, grafted, branch or hyperbranched. The matrix polymer may be a thermoplastic or a thermoset resin. Illustrative of useful thermoplastic resins are cellulose and its derivatives (cellulosic): cellulose ethers such as methyl cellulose, ethyl cellulose, hydroxyethyl cellulose, hydroxypropyl cellulose, and cyanoethyl cellulose, and cellulose esters such as triacetyl cellulose (TAC), diacetyl cellulose (DAC), cellulose acetate propionate (CAP), cellulose acetate butyrate (CAB), cellulose acetate phthalate, cellulose acetate trimellitate and cellulose nitrate. The polymer can include polyolefins such as (linear) low and high density poly(ethylene), poly(propylene), chlorinated low density poly(ethylene), poly(4-methyl-l-pentene), and poly(ethylene) and cyclic polyolefins; poly(styrene); polyxylyene; ; polyimide, vinyl polymers and their copolymers such as poly(vinylcarbazole), poly(vinyl acetate), poly(vinyl alcohol), poly(vinyl chloride), poly(vinyl butyral), poly(vinylidene chloride), ethylene-vinyl acetate copolymers, and the like; polyacrylics their copolymers such as poly(ethyl acrylate), poly(n-butyl acrylate), poly(methylmethacrylate), poly(ethyl methacrylate), poly(n-butyl methacrylate), poly(n-propyl methacrylate), poly(acrylamide), polyacrylonitrile, poly(acrylic acid), ethylene-acrylic acid copolymers; ethylene-vinyl alcohol copolymers; acrylonitrile copolymers; methyl methacrylate-styrene copolymers; ethylene-ethyl acrylate copolymers; methacrylated budadiene-styrene copolymers, and the like; polycarbonates such as poly(methane bis(4-phenyl)carbonate), poly(1,1-ether bis(4-phenyl)carbonate), poly(diphenylmethane bis(4-phenyl)carbonate), poly(1,1-cyclohexane bis(4-phenyl)carbonate), poly(2,2-bis-(4-hydroxyphenyl)propane)carbonate and the like; polyether; polyketone; polyphenylene; polysulfide; polysulfone; polylactones such as poly(pivalolactone), poly(caprolactone) and the like; polyurethanes; linear long-chain diols such as poly(tetramethylene adipate), poly(ethylene adipate), poly(l,4-butylene adipate), poly(ethylene succinate), poly(2,3-butylenesuccinate), polyether diols and the like; polyether ether ketones; polyamides such as poly (4-amino butyric acid), poly(hexamethylene adipamide), poly(6-aminohexanoic acid), poly(m-xylylene adipamide), poly(p-xylyene sebacamide), poly(2,2,2-trimethyl hexamethylene terephthalamide), poly(metaphenylene isophthalamide) (NOMEX), poly(p-phenylene terephthalamide)(KEVLAR), and the like; polyesters such as poly(ethylene azelate), poly(ethylene-1,5-naphthalate), poly(ethylene-2,6-naphthalate), poly(l,4-cyclohexane dimethylene terephthalate), poly(ethylene oxybenzoate) (A-TELL), poly(para-hydroxy benzoate) (EKONOL), poly(l,4-cyclohexylidene dimethylene terephthalate) (KODEL) (cis), poly(l,4-cyclohexylidene dimethylene terephthalate) (KODEL) (trans), polyethylene terephthlate, polybutylene terephthalate and the like; poly(arylene oxides) such as poly(2,6-dimethyl-1,4-phenylene oxide), poly(2,6-diphenyl-1,4-phenylene oxide) and the like; poly(arylene sulfides) such as poly(phenylene sulfide) and the like; polyetherimides; ionomers; poly(epichlorohydrins); furan resins such as poly(furan); silicones such as poly(dimethyl siloxane), poly(dimethyl siloxane), poly(dimethyl siloxane co-phenylmethyl siloxane) and the like; especially fluorinated polymers and their co-polymers including polytetrafluoroethylene, poly(tetrafluoroethylene-co-hexafluoropropylene), poly(ethylene-co-tetrafluoroethylene), poly(ethylene-co-hexafluoropropylene); and polyacetals. Other copolymers not specifically stated and/or mixtures of these aforementioned polymers can also be used.

In accordance with an embodiment, the optically transparent polymer substrate is polytetrafluoroethylene-co-hexafluoropropylene.

As used herein, the term “discrete area” means that the nanoparticles prepared using the inventive methods disclosed herein are located in the regions of the substrate which are irradiated by the light source. Thus, one of ordinary skill in the art would understand that the inventive methods allow patterns of nanoparticles to be developed in selected areas of the nanocomposite substrate where one directs the light source. In certain embodiments, this capability can allow different areas of the substrate to have different physical properties based on the location of the light source.

In accordance with some alternative embodiments, the “discrete area” means the areas of the optically transparent substrate are located in the regions of the substrate which are irradiated by the light source. Thus allowing for the metal or metal oxide compounds or precursor compounds to differential diffuse into those discrete areas irradiated at a higher concentration than in the surrounding locations of the substrate.

In accordance with an embodiment, the laser beam has an optical wavelength of 400 nm, a pulse width of 135 fs, a pulse repetition frequency of 1 kHz, and an average pulse fluence of 90 μJcm⁻², including 10, 20, 30, 40, 50, 60, 70, 80, 90, 100, 200 up to 500 μJcm⁻². Wavelengths include those not absorbed or scattered by the matrix but interact primarily with embedded nanoparticles—typically 300 nm-3 μm, including 400 nm, 500 nm, 600 nm, 800 nm, 1 μm, 2 μm up to 3 μm. Pulse widths range from 10 s of femtoseconds to hundreds of femotseconds including 20, 30, 40, 50, 100, 200, 300, 400 and 500 fs, pulse repetition frequencies can range from 1 Hz to 1000 MHz, including 2, 3, 4, 5, 10, 20, 30 , 40, 50, 100, 200, 300, 400, 500, 600, 800 and 1000 Mhz, and average pulse fluences can range from lOs nJ/cm² to 100s μJ/cm², including 20, 30, 40, 50, 60, 70, 80, 90 100 nJ/cm² to 10, 20, 30 , 40, 50, 100, 200, 300, 400, up to 500 μJ/cm².

In accordance with an embodiment the present invention also provides that when the precursor diffusional pathways in the polymer are actively controlled, then the concentration of precursor within the matrix can be spatially adjusted, thereby providing a degree of control over the discrete locations or patterns where particles are formed. The underlying premise of the inventive process is that spatially controlled heating of the matrix using photothermal methods can be used to pattern diffusion channels and provide for rapid ingress of precursor resulting in a spatially varying precursor concentration profile or pattern in the matrix. Subsequent decomposition of the precursor will result in a patterned nanocomposite where the number density of particles in the matrix varies spatially.

Coupled thermal and diffusion fields have been investigated for many years, and so too have photothermal processes, but little work has been performed in areas related to diffusion control using photothermal methods. The basis for the inventive concepts is that the species diffusion coefficient in many materials systems is strongly temperature-dependent so that any increase in temperature can bring about significant increases in diffusion. For many processes, the diffusivity temperature-dependence follows an Arrhenius form—e^{-E}^{_{A}}^{/k}^{_{B}}^{T} where E_{A} is an activation energy for the governing mechanism, and the rate of species transport can be actively controlled by adjusting temperature. In polymers, only modest temperature rises are needed to significantly increase precursor transport. For example, the activation energy for gas permeation in polytetrafluorehtylene (PTFE) is approximately 0.2 eV, so that moderate localized temperature increases of 20° C. (at various processing temperatures used for precursor diffusion) can increase the diffusion coefficient by 30-60%.

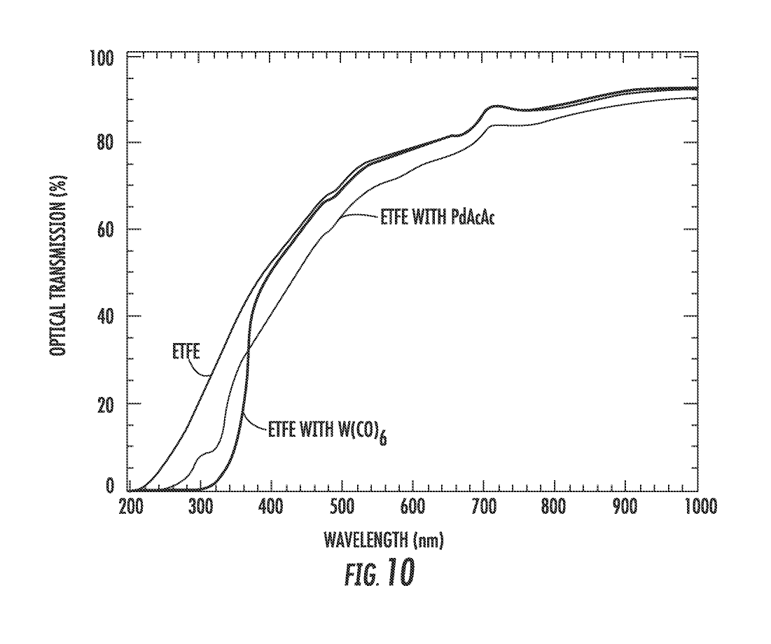

Owing to the low thermal diffusivities of the matrix polymers used to form PMNCs in this invention, these types of temperature rises can be induced with relatively low power lasers that are absorbed by the polymer. The challenge is to select a laser wavelength that heats the polymer but does not induce photolysis of the precursor, as we want the precursor to diffuse into the polymer before decomposition reactions are induced (either thermally or photonically). The optical transmission spectrum for the matrix polymer poly(ethylene-co-tetrafluoroethylene) (or ETFE) from ultraviolet to near infrared wavelengths is shown in FIG. 10, along with corresponding spectra when the polymer contains either the precursor palladium hexafluoroacetylacetonate or tungsten hexacarbonyl.

Absorption in ETFE increases in the ultraviolet but this is also true for the precursors—organic compounds readily undergo photolysis in the ultraviolet. At longer wavelengths, optical absorption by the precursors appears to decline more rapidly than absorption for the matrix—photothermal heating of the matrix might be carried out using near-infrared wavelengths without significant excitation of precursors. These wavelengths can be used to produce localized heating of the matrix materials without significant collateral precursor decomposition.

Thus, in accordance with another embodiment, the present invention provides a method for making a patterned nanocomposite comprising: a) contacting an optically transparent substrate with at least one photocatalytic decomposable metal oxide precursor compound such that the decomposable metal oxide precursor compound diffuses into the optically transparent polymer substrate to create a decomposable metal oxide precursor-polymer composite; and b) selectively exposing one or more discrete areas of the decomposable metal oxide precursor-polymer composite to a light source at a wavelength wherein the optically transparent substrate absorbs the light in a significantly greater amount than the photocatalytic decomposable metal oxide precursor compound; and allowing the photocatalytic decomposable metal oxide precursor compound to diffuse into the discrete areas.

In accordance with a further embodiment, the present invention provides a method for making a patterned nanocomposite comprising: a) contacting an optically transparent substrate with at least one photocatalytic decomposable metal precursor compound such that the decomposable metal precursor compound diffuses into the optically transparent polymer substrate to create a decomposable metal precursor-polymer composite; and b) selectively exposing one or more discrete areas of the decomposable metal precursor-polymer composite to a light source at a wavelength wherein the optically transparent substrate absorbs the light in a significantly greater amount than the photocatalytic decomposable metal precursor compound; and allowing the photocatalytic decomposable metal precursor compound to diffuse into the discrete areas.

### EXAMPLES

Laser Heating. If we consider the case of an individual nanoparticle irradiated by a single femtosecond laser pulse, we can assume that the nanoparticle is adiabatically heated without any loss of heat to the surrounding medium during and immediately after exposure. Laser pulse energy is initially deposited in conduction electrons that undergo a thermalization process in which they interact with other conduction electrons via scattering processes (reaching equilibrium ˜50 fs after exposure) and exchange energy with phonons until thermal equilibrium is reached between the electrons and the lattice (˜50 ps post exposure) (Phys. D-Appl. Phys. 41 (18) (2008)). It is at this point that the particle can be assumed to be at a relatively uniform temperature owing to the deposition depth as well as the rapid rate of energy transport. Phonon-phonon coupling between the nanoparticle and its surroundings generally takes place on a time scale longer than 50 ps, typically on the order of 100-1000 ps before thermal equilibrium is reached between the nanoparticle and its immediate surroundings. For these reasons, we can assume a maximum change in temperature that the nanoparticle experiences due the absorption of a single femtosecond pulse which can be described using the following expression:

$$Δ T = \frac{{E}_{pulse} {σ}_{np}}{{c}_{p , np} {m}_{np}} \qquad ( 1 )$$

where ΔT is the adiabatic temperature rise, Eₚᵤₗₛₑ is the laser pulse fluence, σₙₚ is the absorption cross section of the nanoparticle, c_{p,np} is the specific heat capacity of the nanoparticle, and mₙₚ is the mass of the nanoparticle. The cross section of the nanoparticle can be calculated using Mie scattering theory (or other similar developments) and depends on nanoparticle size, shape, laser wavelength as well as the properties of the matrix. For a silver nanoparticle 10 nm in diameter exposed to a femtosecond laser pulse (90 μJcm⁻²), an adiabatic temperature rise of 285 K is calculated using Eq. (1).

The energy transport away from a particle can be modeled using classical thermal diffusion descriptions. If a spherical particle embedded in an infinite medium is considered then the corresponding equations are (Physical Review B 84 (3) (2011)):

ρₙₚcₙₚ∂₁T(r,t)=κₙₚ∇²T(r,t) for r<R (2)

ρₘcₘ∂₁T(r,t)=κₘ∇²T(r,t) for r>R (3)

with the boundary conditions at r=R:

κₘ∂₁T(R′, t)=κₘₚ∂ᵣT(R′, t) (4)

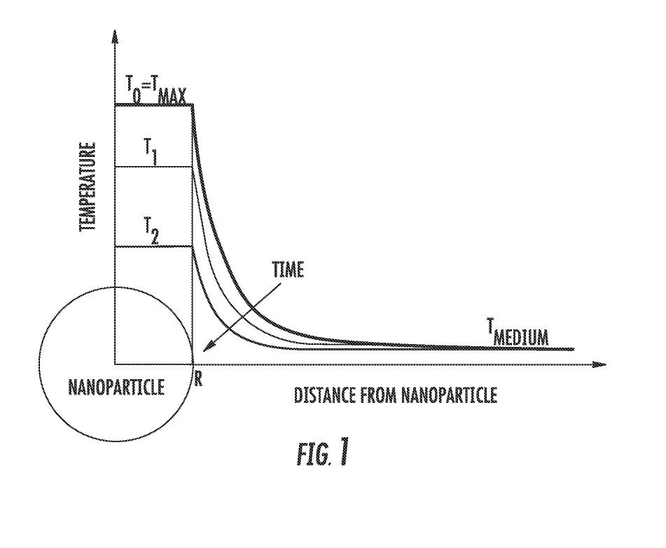

T(R′,t)=T(R′, t) (5)

where ρₙₚ, cₙₚ κₙₚ are the mass density, specific heat capacity, and thermal conductivity of the nanoparticle respectively, and ρₘ, cₘ κₘ are the mass density, specific heat capacity, and thermal conductivity of the surrounding medium respectively. These equations can be solved numerically and can be used to model experimental measurements of particle heating using femtosecond pump-probe temperature measurements. Based on the work of Hu et al. (J. Phys. Chem. B 106 (28), 7029-7033 (2002)), and Baffou et al.(Physical Review B 84 (3) (2011)) we know that the regions immediately surrounding the irradiated nanoparticle (10-20 nm) will experience a temperature rise that depends on the temperature of the nanoparticle and decreases rapidly as a function of distance away from the nanoparticle. We can assume that only the immediate environment of each irradiated nanoparticle will reach a sufficient temperature to decompose the vaporized organometallic precursor. A diagram that illustrates a simplified temperature evolution of a heated nanoparticle is shown in FIG. 1.

### EXAMPLE 1

The starting material for the first series of experiments was a silver polymer nanocomposite synthesized using a modified CVD nanoinfusion process. This process begins by placing a FEP polymer film in a reaction vessel with vinyltriethylsilane-(hexafluoroacetylacetonate)silver(I) [Ag(CF₃COCHCOCF₃)(C₈H₁₈—Si)], an organometallic silver precursor. This was performed in a glove box under an argon atmosphere in order to keep the silver precursor from reacting with oxygen in air. The bottom portion of the reaction vessel, which contained the silver precursor, was then placed in a dewar containing liquid nitrogen. After the precursor was frozen, the vessel was evacuated to a vacuum level of 100 mTorr. The vessel was then sealed, removed from the liquid nitrogen dewar, and allowed to return to room temperature (20° C.). This process was performed two more times to sufficiently remove any air trapped within the liquid precursor. Finally, the evacuated reaction vessel was placed in an oven and heated according to a predetermined heating schedule. The reaction vessel was first heated to 140° C. for 2 hours in order to vaporize the precursor allowing it to diffuse into the polymer film. The reaction vessel was further heated to 180° C., which is the thermal decomposition temperature of the silver precursor, and held at this temperature for 1 hour. Afterwards the vessel was gradually cooled back to room temperature and evacuated again in order to remove any remaining precursor and decomposition gases. This entire procedure was performed twice on the same polymer resulting in a Ag-FEP nanocomposite (designated as a 2× material) that was used as the starting material for laser processing.

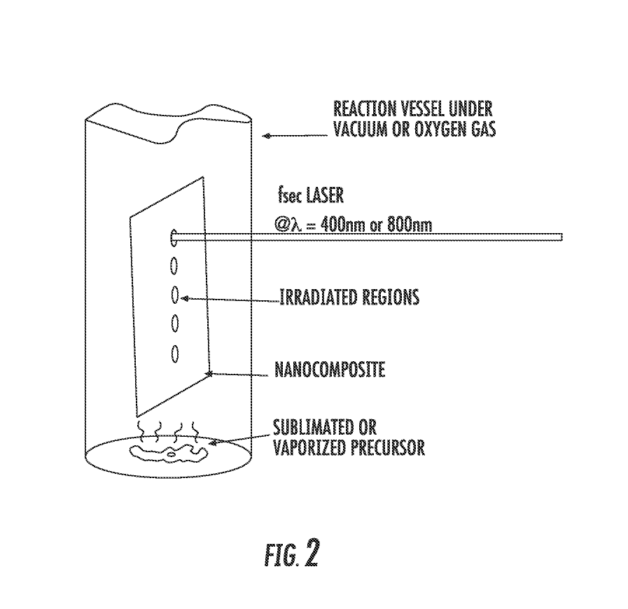

The next step was to place the 2× Ag-FEP nanocomposite in a reaction vessel with 100 mg of tungsten carbonyl, a tungsten/tungsten oxide precursor obtained from STREM Chemicals. The reaction vessel was evacuated to 100 mTorr, back filled with oxygen gas to a pressure of 400 Torr, and then placed in a custom oven chamber with an optical window. The vessel was then heated to 140° C. and held at this temperature for 45 minutes, allowing for sublimation of tungsten carbonyl and sufficient diffusion into the 2× Ag-FEP nanocomposite film. The nanocomposite was then selectively exposed to a frequency-doubled femtosecond laser (optical wavelength—400 nm, pulse width—135 fs, pulse repetition frequency—1 kHz, average pulse fluence—90 μJcm⁻²). Regions of the polymer were optically exposed for up to 10 minutes. Afterwards, the reaction vessel was allowed to cool to room temperature. A diagram of the laser synthesis process is shown in FIG. 2.

### EXAMPLE 2

A similar procedure was also used to obtain a tungsten oxide nanocomposite. Using tungsten carbonyl [W(CO)₆] as the organometallic precursor, the vessel was heated to140° C. and held at that temperature for 3 hours to allow the tungsten carbonyl to sublimate and diffuse into the FEP polymer film. It was then heated to 165° C., the experimentally determined temperature at which tungsten carbonyl decomposed and held at that temperature for 2 hours, resulting in the nucleation of tungsten oxide nanoparticles within the bulk of the polymer film. This infusion process was performed twice to obtain a 2× WO₃-FEP nanocomposite. The 2× WO₃ nanocomposite was then placed in a reaction vessel with a small amount of the silver precursor described above. The vessel was evacuated and placed in an oven with an optical window and heated to 100° C. After 45 minutes at 100° C., the sample was selectively irradiated with femtosecond laser pulses. For this processing, the laser pulses were unamplified and were not doubled (optical wavelength ˜800 nm, pulse width—100 fs, pulse repetition frequency—80 MHz, average pulse fluence—6 nJcm⁻²) to optimize photothermal heating.

All materials were optically characterized using a Varian UV/Vis spectrometer before and after laser processing. Transmission electron microscopy (TEM) was performed on a 100 kV instrument (FEI). The TEM samples were prepared using a diamond microtome to cross-section the nanocomposite into 90-200 nm thick samples which were then mounted on a copper TEM grid.

### EXAMPLE 3

Two different materials systems (a 2× Ag-FEP nanocomposite and a 2× WO₃ nanocomposite) were patterned using different temperatures and laser irradiation conditions. They were both characterized using UV/Vis optical spectroscopy in order to determine the changes to their optical properties as a result of processing and were also characterized using TEM microscopy in order to observe structural and size changes in the nanoparticles in the polymer films.

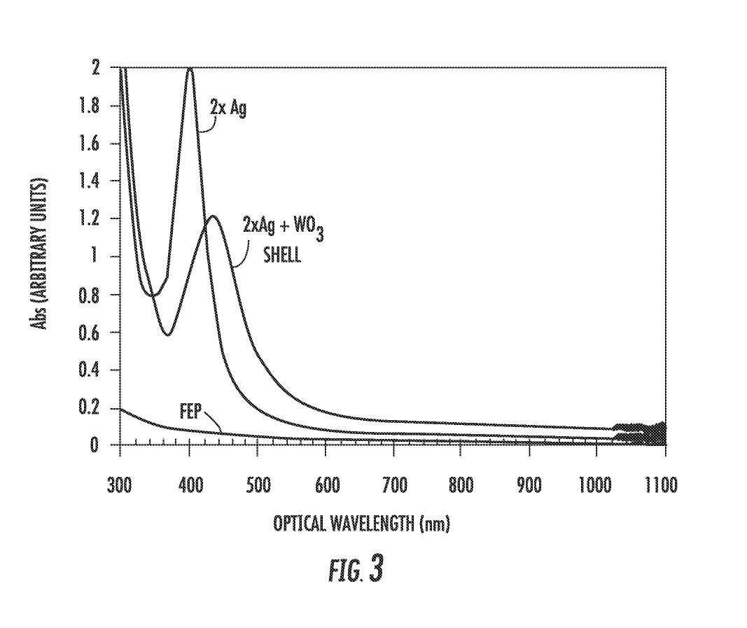

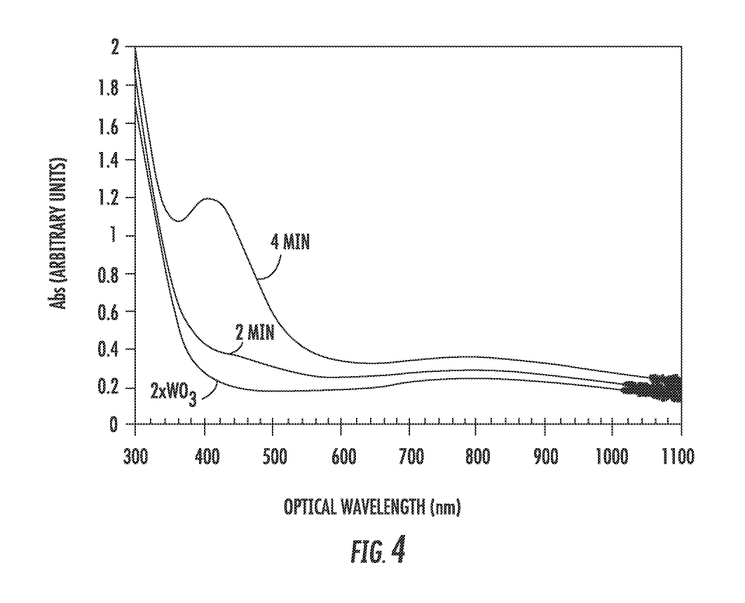

Optical Characterization. The UV/Vis spectrum for an unprocessed 2× Ag nanocomposite is shown in FIG. 4 and shows a large SPR located at an optical wavelength of 402 nm. After exposing the nanocomposite for 20 minutes to 90 μJcm⁻² pulses at 400 nm, the nanocomposite displayed a 40 nm red shift in its SPR to 442 nm (also shown in FIG. 3). It should be noted that the 2× Ag nanoparticles absorb very strongly at 400 nm while the other materials in the nanocomposite system absorb very weakly, and therefore the silver nanoparticles interact with the laser light more so than the other materials. The broader SPR peak for the fs-processed material may be due to changes in the polydispersity of post-exposure nanoparticles. Also shown in FIG. 3 is the neat, unprocessed FEP polymer film. Its high optical transmission ensures that it is not primarily responsible for the optical properties of the nanocomposite and also does not play a significant role in absorbing the laser pulse energy. The shift in the SPR of silver can be explained with optical models, and has been observed previously by Wang et al. when coating silver nanoparticle arrays with thin coatings of WO₃ (Adv. Mater. 15 (15), 1285-+(2003)).

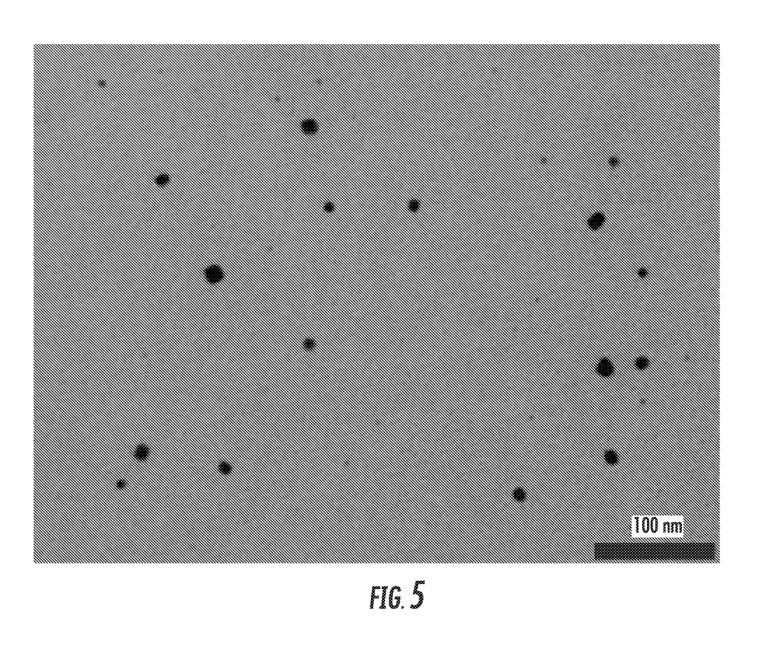

The other material system studied was a 2×WO₃-FEP nanocomposite. Its optical properties before and after laser irradiation are shown in FIG. 5. Tungsten oxide is a wide band-gap semiconductor with a bandgap energy, E_{g}, of 3.1 eV; when photons have an energy larger than the bandgap, electrons are promoted from the valence band to the conduction band. The tungsten oxide material (while in the presence of a vaporized silver precursor) was exposed at two separate locations on the sample—one for 2 minutes and another for 4 minutes. Both locations were irradiated with pulses at a relatively low fluence and high repetition rate (optical wavelength—800 nm, repetition rate—80 MHz, pulse fluence—6 nJcm ²). The 800 nm wavelength was chosen due to the broad optical absorption of tungsten oxide which has a maximum absorption at a wavelength of 840 nm. This broad absorption is due to a difference in valence states of tungsten atoms at distinct lattice sites, which is caused by an oxygen deficiency within the WO₃ nanoparticle (J. App. Phys. 74 (7), 4527-4533 (1993)). As can be seen in FIG. 4, the material exposed for 4 minutes exhibits a sharp SPR peak for silver at 430 nm, while the material exposed for 2 minutes exhibited a much weaker and broader SPR shoulder located at 430nm.

Despite the low pulse fluences used to process the tungsten oxide nanocomposites, a very strong SPR peak develops as a result of silver precursor decomposing in the polymer. The change in temperature of the tungsten oxide nanoparticles for such low pulse fluences is correspondingly small and cannot account for the decomposition of the silver precursor. It is thought that the tungsten oxide nanoparticles are acting as catalytic sites and decomposing the silver precursor at the surface of the tungsten oxide nanoparticles. Yet, while tungsten oxide is a well-known photocatalytic material, it typically requires a photon energy greater than its band-gap to initiate its photocatalytic response and, consequently, it is likely that multiphoton events are involved in the processes reported here (J. Phys. Chem. C 112 (1), 61-68 (2008)). The probability of the two-photon absorption depends upon the intensity of the laser, the two-photon absorption cross-section, and the particle number density in the nanocomposite. The two-photon absorption cross-section for the tungsten oxide nanoparticles is not known, and the particle distribution in the polymer is difficult to calculate, and, as a result, it is difficult to accurately calculate a probability for the two-photon process in this tungsten oxide nanocomposite. However, because the changes in the material we observe are only occurring after exposure to femtosecond laser irradiation and do not occur merely from heating the material, it is thought that two-photon absorption is occurring and initiating a photocatalytic response.

### EXAMPLE 4

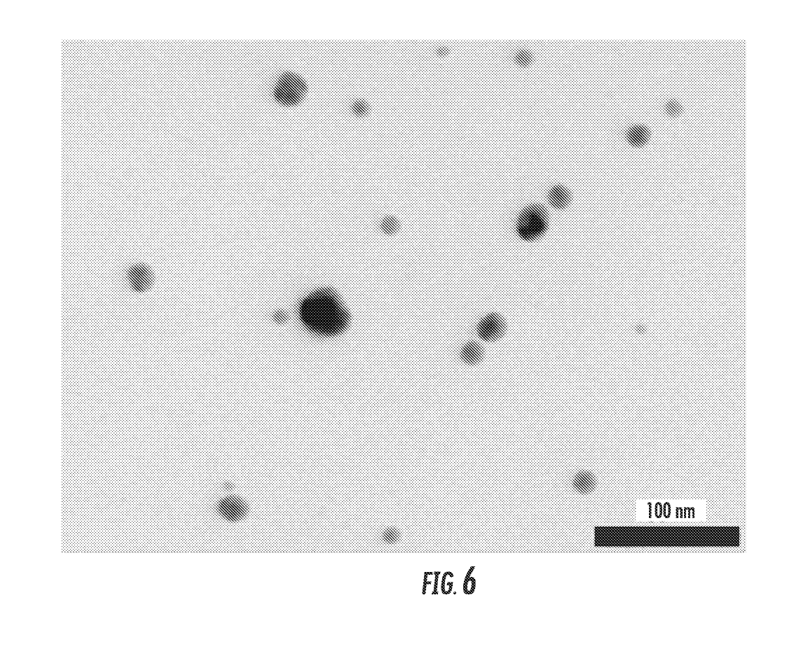

TEM Microscopy. Silver nanoparticles before femtosecond irradiation displayed an average radius of 5 nm, and had cubic and spherical shapes with no core-shell geometries shown in FIG. 5. After exposure, more complicated geometries were observed, including silver-core, tungsten-oxide-shell nanoparticles shown in FIG. 6. The shell thicknesses varied from 5 to 8 nm with some silver nanoparticles encompassed by tungsten oxide while others were not. In addition, the near-surface of the polymer had nanoparticles with larger diameters as well as more core-shell nanoparticles than those of the nanoparticles within the bulk of the polymer film. This indicates that the growth mechanism of the nanoparticles and shells somewhat depends on the diffusion kinetics of the FEP polymer and the tungsten carbonyl precursor species.

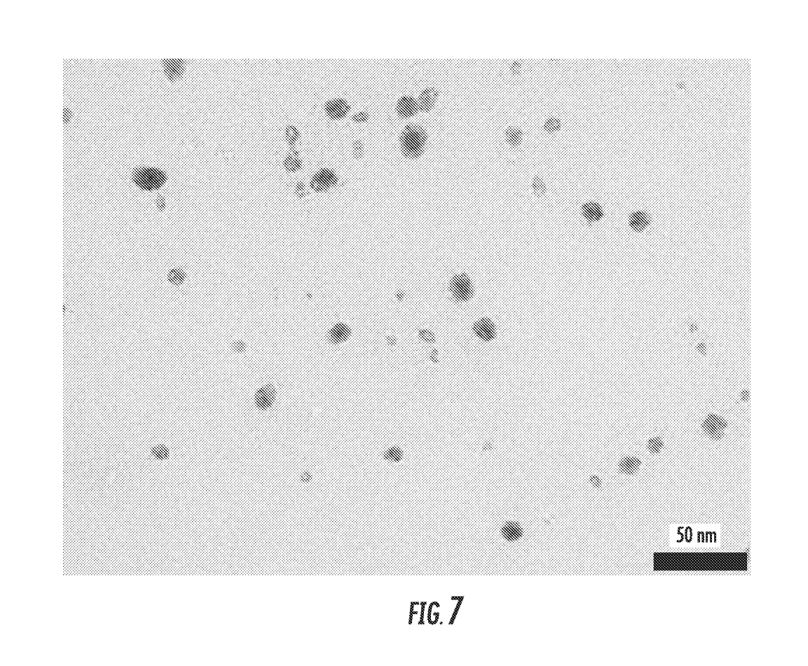

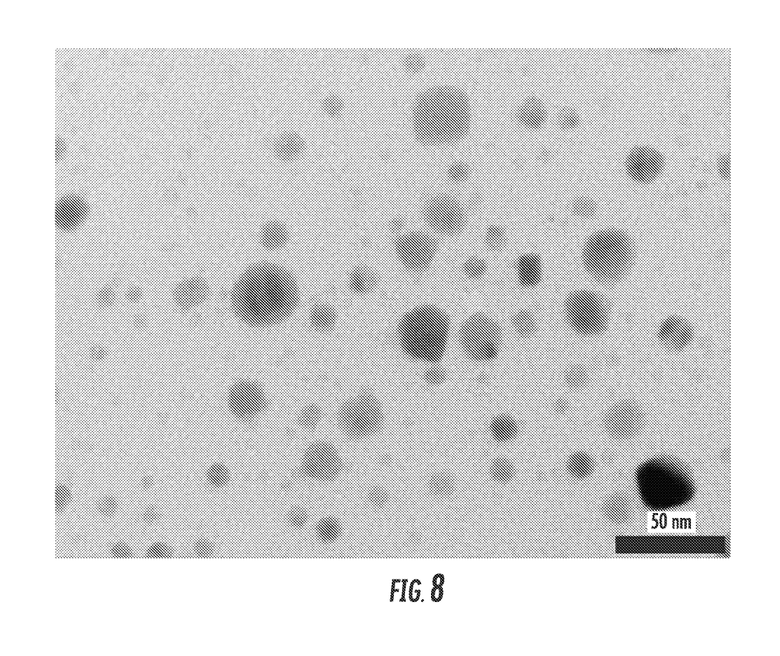

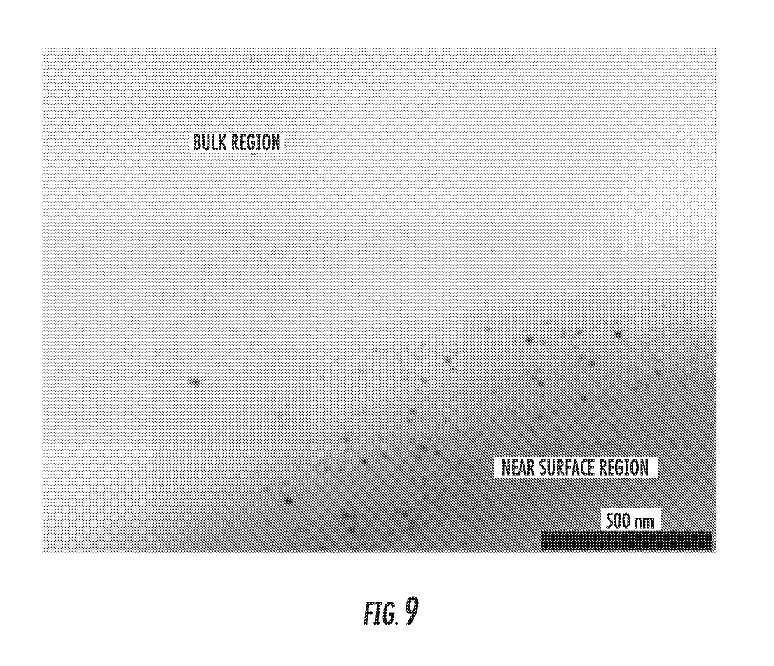

The growth of more complicated geometries and larger nanoparticles was also apparent in 2×WO₃-FEP nanocomposites as a result of exposure to laser irradiation while in the presence of a silver precursor. In FIG. 7, a 2×WO₃-FEP nanocomposite is shown prior to femtosecond laser irradiation, showing particles with a roughly spherical shape and an average nanoparticle radius of 4.3 nm. In FIG. 8, it can be observed that the tungsten nanoparticles have diameters between 6 to 10 nm, while the larger core-shell nanoparticles have diameters between 10 and 20 nm. Also of note are cubic, semi-cubic/round, as well as octahedral core-shell nanoparticles. This materials system also exhibited larger nanoparticles near the surface of the polymer, as can be seen in FIG. 9.

After exposure to femtosecond laser irradiation, both the 2×Ag and 2×WO₃ samples were found to have a broader particle size distribution. The inhomogeneity of the particle size is most likely due to a variety of factors involved in the decomposition of the chemical precursor and the growth of shell around existing nanoparticles. The decomposition of the precursor depends on the thermal gradient as well as presence of the precursor gas in the vicinity of each nanoparticle. Particles in close proximity to each other may enhance the localized temperature in the matrix, which could lead to a greater amount of precursor decomposition, leading to larger particles. In addition, the amount of precursor in the vicinity of each nanoparticle depends on the free volume of the polymer matrix. Some nanoparticles may have a larger amount of polymer free volume in their local environment and therefore have access to greater amounts of precursor, which would allow them to grow to larger sizes than particles with access to less free volume, resulting in a broader distribution.

Using a modified CVD infusion process and femtosecond laser irradiation, we have demonstrated the ability to create core-shell nanoparticles of silver and tungsten oxide nanoparticles embedded within the bulk of a polymer matrix. Changes in the optical properties and changes in the structure, size, and shape of the nanoparticles were observed as a result of processing. It was also observed that core-shell nanoparticles preferentially nucleated in the near surface region of the polymer, indicating a precursor-diffusion-dependent process for the growth of core-shell nanoparticles. With the use of optical masks and multiple precursor chemicals, it may be possible to create nanoparticles or core-shell nanoparticles with drastically different compositions in close proximity to each other. Since the mechanism for precursor decomposition is limited to the surface of the nanoparticles within the polymer, it is possible to control the chemistry, size, and shape of nanoparticles within a polymer matrix on a nanoscale.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A method for making a nanocomposite comprising:
a) contacting an optically transparent substrate with an decomposable metal precursor compound such that the decomposable metal precursor compound diffuses into the optically transparent substrate to create a decomposable metal precursor-substrate composite;
b) decomposing the decomposable metal precursor-polymer composite of a) and creating a first nanocomposite substrate comprising metal nanoparticles dispersed in the substrate;
c) contacting the first nanocomposite substrate of b) with a decomposable metal oxide precursor compound such that the decomposable metal oxide precursor compound diffuses into the first nanocomposite substrate of c) to create a decomposable metal oxide precursor-nanocomposite substrate; and
d) selectively exposing one or more discrete areas of the a decomposable metal oxide precursor-nanocomposite substrate of c) to a light source at a wavelength in which the metal nanoparticles of b) in the metal oxide precursor-nanocomposite substrate absorb the laser light at a significantly greater than that the decomposable metal oxide precursor compound in the substrate, at a sufficient pulse width, pulse repetition and sufficient pulse fluence, and for a sufficient period of time to decompose the decomposable metal oxide precursor compound in the metal oxide precursor-nanocomposite substrate to create a nanocomposite comprising a substrate having nanoparticles comprising a metal core and a metal oxide shell in the discrete areas.

2. A method for making a nanocomposite comprising:
a) contacting an optically transparent substrate with a photocatalytic decomposable metal oxide precursor compound such that the decomposable metal oxide precursor compound diffuses into the optically transparent substrate to create a decomposable metal oxide precursor-substrate composite;
b) decomposing the photocatalytic decomposable metal oxide precursor-polymer composite of a) and creating a first nanocomposite substrate comprising metal oxide nanoparticles dispersed in the substrate;
c) contacting the photocatalytic nanocomposite substrate of b) with a decomposable metal precursor compound such that the decomposable metal precursor compound diffuses into the photocatalytic nanocomposite substrate of c) to create a decomposable metal precursor-nanocomposite substrate; and
d) selectively exposing one or more discrete areas of the a decomposable metal precursor-nanocomposite substrate of c) to a light source at a wavelength in which the photocatalytic nanocomposite substrate absorbs the laser light at a significantly greater than that the decomposable metal precursor compound in the substrate, at a sufficient pulse width, pulse repetition and sufficient pulse fluence, and for a sufficient period of time to photocatalytically decompose the decomposable metal precursor compound in the nanocomposite substrate to create a nanocomposite comprising a substrate having nanoparticles comprising a metal oxide core and a metal shell in the discrete areas.

3. A method for making a nanocomposite comprising:
a) placing an optically transparent substrate into a first reaction vessel;
b) placing an organometallic metal precursor compound into the reaction vessel;
c) vaporizing the organometallic metal precursor compound in the first reaction vessel such that the organometallic metal precursor compound diffuses into the optically transparent substrate to create a organometallic metal precursor-substrate composite;
d) heating the organometallic metal precursor-polymer composite of c) to decompose the organometallic metal precursor and creating a first nanocomposite substrate comprising metal nanoparticles dispersed in the substrate;
e) cooling first reaction vessel and removing remaining organometallic metal precursor compound and decomposition gases;
f) placing the first nanocomposite substrate of d) into a second reaction vessel;
g) placing a metal oxide precursor compound in the second reaction vessel;
h) optimizing the oxygen concentration in the second reaction vessel;
i) heating the second reaction vessel to allow the metal oxide precursor to subliminate such that the metal oxide precursor compound diffuses into the first nanocomposite substrate of d) to create a metal oxide precursor-nanocomposite substrate;
j) selectively exposing one or more discrete areas of the a metal oxide precursor-nanocomposite substrate of i) to a laser beam at a wavelength in which the metal nanoparticles in the metal oxide precursor-nanocomposite substrate absorb the laser light at a significantly greater than the other compounds in the substrate, at a sufficient pulse width, pulse repetition and average pulse fluence, and for a sufficient period of time to decompose the metal oxide precursor compound in the metal oxide precursor-nanocomposite substrate to create a nanocomposite comprising a polymer substrate having nanoparticles comprising a metal core and a metal oxide shell in the discrete areas.

4. The method of claim 3, wherein the optically transparent polymer substrate is polytetrafluoroethylene-co-hexafluoropropylene (FEP).

5. The method of claim 3, wherein the organometallic metal precursor compound is vinyltriethylsilane-(hexafluoroacetylacetonate)silver(I).

6. The method of claim 3, wherein the metal oxide precursor compound is tungsten carbonyl.

7. The method of claim 3, wherein the oxygen concentration in the second reaction vessel is 400 torr.

8. The method of claim 3, wherein the laser beam has an optical wavelength of 400 nm, a pulse width of 135 fs, a pulse repetition frequency of 1 kHz, and an average pulse fluence of 90 μJcm⁻².

9. The method of claim 3, wherein the laser beam is exposed to one or more discrete areas of the metal oxide precursor-nanocomposite substrate of h) for a period of 10 minutes.

10. The method of claim 1, wherein steps a)-b) are repeated two or more times.

11. The method of claim 1, wherein steps c)-e) are repeated two or more times.

12. A method for making a patterned nanocomposite comprising: a) contacting an optically transparent substrate with at least one photocatalytic decomposable metal oxide precursor compound such that the decomposable metal or metal oxide precursor compound diffuses into the optically transparent polymer substrate to create a decomposable metal or metal oxide precursor-polymer composite; b) selectively exposing one or more discrete areas of the decomposable metal or metal oxide precursor-polymer composite to a light source at a wavelength wherein the optically transparent substrate absorbs the light in a significantly greater amount than the photocatalytic decomposable metal or metal oxide precursor compound; and allowing the photocatalytic decomposable metal or metal oxide precursor compound to diffuse into the discrete areas.

13. The method of claim 12, wherein the optically transparent polymer substrate is poly(ethylene-co-tetrafluoroethylene) (ETFE).

14. The method of claim 13, wherein the organometallic metal precursor compound is vinyltriethylsilane-(hexafluoroacetylacetonate)silver(I).

15. The method of claim 13, wherein the metal oxide precursor compound is tungsten carbonyl.
